(19) United States
(12) Patent Application Publication
(10) Pub. No.: US 2025/0365897 A1
(43) Pub. Date: Nov. 27, 2025

(54) COOLING MODULE AND ELECTRONIC APPARATUS

(71) Applicant: Lenovo (Singapore) Pte. Ltd., Singapore (SG)

(72) Inventors: Hao-Yu Wang, Kanagawa (JP); Shuokun Shi, Kanagawa (JP); Yusuke Onoue, Kanagawa (JP); Yuki Saigusa, Kanagawa (JP); Akinori Uchino, Kanagawa (JP)

(73) Assignee: Lenovo (Singapore) Pte. Ltd., Singapore (SG)

(21) Appl. No.: 19/217,885

(22) Filed: May 23, 2025

(30) Foreign Application Priority Data
May 23, 2024 (JP) 2024-084105

(51) Int. Cl. H05K 7/20; G06F 1/20

(52) U.S. Cl. CPC H05K 7/20336; G06F 1/203; H05K 7/20154

(57) ABSTRACT

A cooling module that is mounted in an electronic apparatus including a heating element includes a first fan having an outlet, a second fan having an outlet, a first heat sink disposed to face the outlet of the first fan, a second heat sink disposed to face the outlet of the second fan, and a heat pipe configured to transport heat from the heating element to the first heat sink and the second heat sink, in which the heat pipe includes a first pipe portion for connecting to the heating element, a second pipe portion branched from one end part of the first pipe portion and connected to the first heat sink, and a third pipe portion branched from the one end part of the first pipe portion and connected to the second heat sink.

### BACKGROUND OF THE INVENTION

### Cross-Reference to Related Applications

This application claims priority to Japanese Patent Application No. 2024-084105 filed on May 23, 2024, the contents of which are hereby incorporated herein by reference in their entirety.

### Technical Field

The present invention relates to a cooling module and an electronic apparatus equipped with the cooling module.

### Background

An electronic apparatus such as a laptop PC is equipped with a cooling module that cools a heating element such as a CPU. The cooling module absorbs heat generated by the heating element and radiates the heat to an outside.

Japanese Patent No. 7349537 discloses a cooling module including a pair of left and right fans, a pair of heat sinks disposed facing respective outlets of the fans, and two heat pipes that transport heat from a heating element to the heat sinks. One end part of each of the two heat pipes is adjacent to the other and connected to the heating element, and the other end parts are connected to the left and right heat sinks, respectively.

As in the configuration of Japanese Patent No. 7349537, the cooling module in the related art uses two heat pipes to transport heat from the heating element to the left and right heat sinks. With this configuration, the heat pipes can transport heat to each heat sink with high efficiency, thereby achieving high cooling performance. However, in this configuration, since two heat pipes are used, a component cost is high, and a work cost for assembling the heat pipes is also high.

### SUMMARY

Embodiments of the of the present invention provide a cooling module capable of reducing a cost while ensuring cooling performance, and an electronic apparatus equipped with the cooling module.

A cooling module according to a first aspect of the present invention is a cooling module that is mounted in an electronic apparatus including a heating element, the cooling module including a first fan having an outlet, a second fan having an outlet, a first heat sink disposed to face the outlet of the first fan, a second heat sink disposed to face the outlet of the second fan, and a heat pipe configured to transport heat from the heating element to the first heat sink and the second heat sink, in which the heat pipe includes a first pipe portion for connecting to the heating element, a second pipe portion branched from one end part of the first pipe portion and connected to the first heat sink, and a third pipe portion branched from the one end part of the first pipe portion and connected to the second heat sink.

An electronic apparatus according to a second aspect of the present invention includes a chassis, a heating element, and a cooling module provided in the chassis and configured to cool the heating element, in which the cooling module includes a first fan having an outlet, a second fan having an outlet, a first heat sink disposed to face the outlet of the first fan, a second heat sink disposed to face the outlet of the second fan, and a heat pipe configured to transport heat from the heating element to the first heat sink and the second heat sink, and the heat pipe includes a first pipe portion connected to the heating element, a second pipe portion branched from one end part of the first pipe portion and connected to the first heat sink, and a third pipe portion branched from the one end part of the first pipe portion and connected to the second heat sink.

One or more embodiments of the present invention reduce a cost while ensuring cooling performance.

### BRIEF DESCRIPTION OF THE DRAWINGS

FIG. 1 is a schematic plan view of an electronic apparatus according to one or more embodiments as viewed from above.

FIG. 2 is a bottom view schematically illustrating an internal structure of a chassis in accordance with one or more embodiments.

FIG. 3 is a schematic cross-sectional plan view of a heat pipe in accordance with one or more embodiments.

FIG. 4 is a schematic configuration diagram of a cooling module according to a modification example in accordance with one or more embodiments.

FIG. 5 is a schematic cross-sectional plan view of the heat pipe illustrated in FIG. 4 in accordance with one or more embodiments.

FIG. 6 is a schematic cross-sectional plan view of a heat pipe according to a modification example of the heat pipe illustrated in FIG. 5 in accordance with one or more embodiments.

### DETAILED DESCRIPTION

Hereinafter, a cooling module and an electronic apparatus according to one or more embodiments of the present invention will be described in detail with reference to the accompanying drawings.

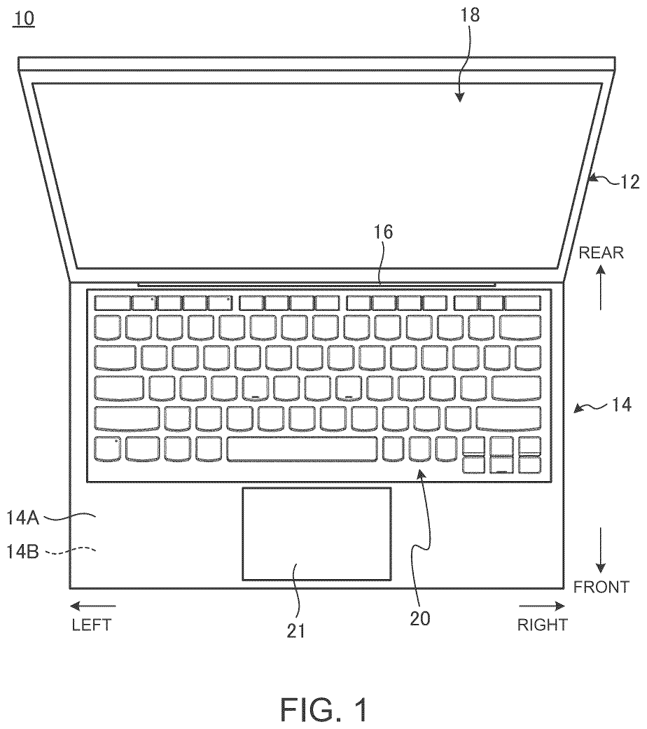

FIG. 1 is a schematic plan view of an electronic apparatus 10 according to one or more embodiments as viewed from above. As illustrated in FIG. 1, the electronic apparatus 10 is a clamshell-type laptop PC in which a cover 12 and a chassis 14 are connected to each other by a hinge 16 so as to be relatively rotatable. In one or more embodiments, the electronic apparatus 10 of the laptop PC is exemplified, but the electronic apparatus may be other than the laptop PC, such as a tablet PC, a smartphone, or a portable game machine.

The cover 12 is a thin flat box body. The cover 12 is provided with a display 18. The display 18 can be configured with, for example, an organic EL display or a liquid crystal display.

The chassis 14 is a thin flat box body. A keyboard 20 and a touch pad 21 are provided on a top surface of the chassis 14. Hereinafter, the chassis 14 and each component mounted in the chassis 14 will be described based on a posture of an operator operating the keyboard 20, in which a depth direction of the chassis 14 will be referred to as a front-rear direction, a width direction of the chassis 14 will be referred to as a left-right direction, and a thickness direction of the chassis 14 will be referred to as a top-bottom direction. Each of these directions is a direction determined for convenience of description, and may be changed depending on a usage state, an installation posture, or the like of the electronic apparatus 10.

The chassis 14 includes a cover member 14A that forms a top surface and four peripheral side surfaces, and a cover member 14B that forms a bottom surface. The top cover member 14A has a substantially bathtub shape with an open bottom surface. The bottom cover member 14B has a substantially flat plate shape and serves as a cover that closes a bottom surface opening of the cover member 14A. The cover members 14A and 14B overlap in the thickness direction and are connected to each other in an attachable and detachable manner. A rear end part of the chassis 14 is connected to the cover 12 by using the hinge 16.

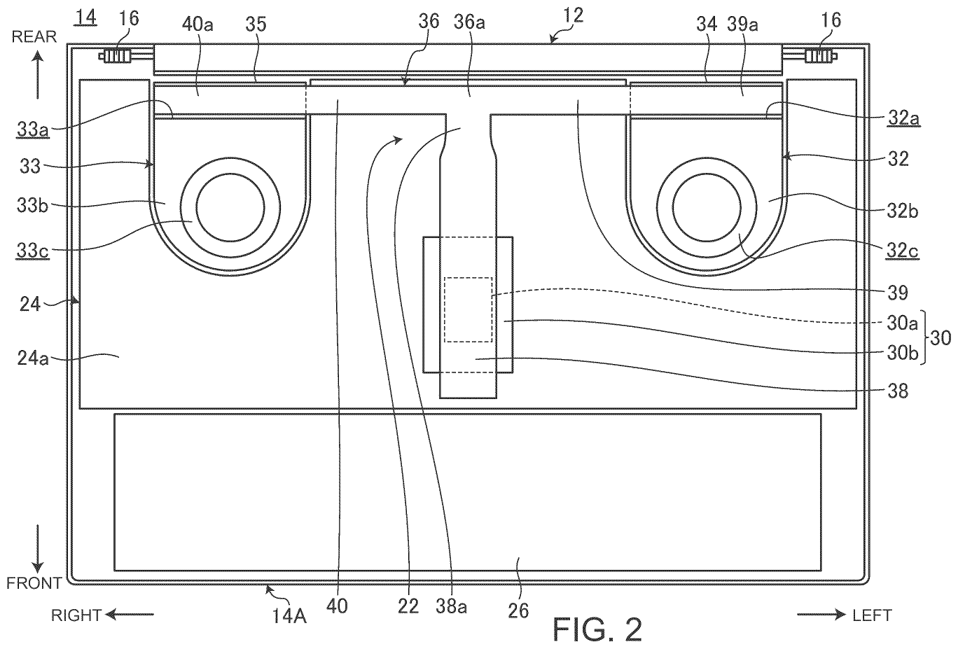

FIG. 2 is a bottom view schematically illustrating an internal structure of the chassis 14. FIG. 2 is a view of an inside of the chassis 14 as viewed from a bottom surface side in a case where the bottom cover member 14B is removed.

As illustrated in FIG. 2, a cooling module 22, a motherboard 24, and a battery device 26 are accommodated inside the chassis 14. Various electronic components, mechanical components, and the like can be further accommodated inside the chassis 14.

The motherboard 24 is a main board of the electronic apparatus 10. The motherboard 24 is disposed close to the rear of the chassis 14 and extends along the left-right direction. The motherboard 24 is a printed circuit board assembly (PCBA) in which various electronic components, such as a central processing unit (CPU) 30, a graphics processing unit (GPU), a power component, a communication module, a memory, and a connection terminal, are mounted on a printed circuit board (PCB). The motherboard 24 is disposed below the keyboard 20 and is screwed to a back surface of the keyboard 20 or an inner surface of the cover member 14A. For example, the motherboard 24 has a top surface that serves as an attachment surface with respect to the cover member 14A, and a bottom surface that serves as a mounting surface 24a for the CPU 30 and the like. The CPU 30 performs computing related to main control or processing of the electronic apparatus 10. The CPU 30 has a configuration in which a die 30a is mounted on a package substrate 30b.

The battery device 26 is a rechargeable battery that serves as a power source of the electronic apparatus 10. The battery device 26 is disposed in front of the motherboard 24 and extends to the left and right along a front end portion of the chassis 14.

Next, a configuration of the cooling module 22 will be described.

The CPU 30 is a heating element having the largest calorific value among electronic components accommodated in the chassis 14. The cooling module 22 mainly absorbs and diffuses heat generated by the CPU 30 and discharges the heat to the outside of the chassis 14. The cooling module 22 is laminated below the motherboard 24 to cover a part of the mounting surface 24a of the motherboard 24. The cooling module 22 can also cool electronic components other than the CPU 30.

As illustrated in FIG. 2, the cooling module 22 includes a pair of left and right fans 32 and 33, a pair of left and right heat sinks 34 and 35, and a heat pipe 36. The cooling module 22 may also include, for example, a heat spreader formed of a copper plate, a vapor chamber that is a plate-shaped heat transport device, and the like.

The fans 32 and 33 are disposed immediately before the heat sinks 34 and 35, respectively. The first fan 32 on the left side is disposed such that an outlet 32a faces the first heat sink 34 on the left side. The second fan 33 on the right side is disposed such that an outlet 33a faces the second heat sink 35 on the right side. The fans 32 and 33 are centrifugal fans in which impellers accommodated inside fan chassis 32b and 33b are rotated by motors. The fans 32 and 33 have intake ports 32c and 33c that are open to one or both of top and bottom surfaces of the fan chassis 32b and 33b. The fans 32 and 33 can cool the heat sinks 34 and 35 by sucking in air from the intake ports 32c and 33c and discharging the air from the outlets 32a and 33a.

The heat sinks 34 and 35 have a structure in which a plurality of plate-shaped fins is arranged at regular intervals in the left-right direction. Each fin stands upright in the top-bottom direction and extends in the front-rear direction. Each fin is formed of a metal having a high thermal conductivity, such as aluminum or copper. A gap, through which air discharged from the fans 32 and 33 passes, is formed between the fins adjacent to each other. The air that has passed through the heat sinks 34 and 35 is discharged to the outside of the chassis 14 through an exhaust port that is open to a rear side surface of the chassis 14.

A configuration of the heat pipe 36 will be described.

The heat pipe 36 is a pipe-shaped heat transport device. The heat pipe 36 has a configuration in which a metal pipe is thinly and flatly crushed and is formed to have an elliptical-shaped cross section and has a sealed space formed therein. The heat pipe 36 realizes high-efficiency heat transport by allowing a working fluid enclosed in the sealed space to flow therethrough while causing a phase change. The metal pipe can be formed of a metal having a high thermal conductivity, such as copper or aluminum. Examples of the working fluid include water, alternative fluorocarbons, acetone, butane, and the like. A wick is provided in the sealed space, and the condensed working fluid is fed by a capillary phenomenon.

As illustrated in FIG. 2, the heat pipe 36 can have a configuration in which a flat metal pipe extends in a substantially T-shape. The heat pipe 36 includes a first pipe portion 38, a second pipe portion 39, and a third pipe portion 40.

The first pipe portion 38 is a portion for connecting to the CPU 30 (die 30a) which is a heating element. The first pipe portion 38 constitutes a heat receiving portion (evaporation portion) that absorbs heat of the CPU 30. A copper plate, thermal conductive grease, or the like can be interposed between the first pipe portion 38 and the CPU 30. The first pipe portion 38 can have a larger diameter than the second pipe portion 39 and the third pipe portion 40. In the configuration example illustrated in FIG. 2, the first pipe portion 38 is disposed to extend along the front-rear direction on the mounting surface 24a. The installation direction, the disposition, and the like of the first pipe portion 38 are not limited to this.

The second pipe portion 39 and the third pipe portion 40 are portions for connecting to the heat sinks 34 and 35. The pipe portions 39 and 40 are branched in two directions from a rear end part (one end part 38a) of the first pipe portion 38 and extend in the left-right direction. As described above, the heat pipe 36 has a configuration in which the three pipe portions 38 to 40 are branched in three directions at a branch portion (branch point) 36a.

An end part 39a of the second pipe portion 39 opposite to the branch portion 36a side is connected to the first heat sink 34. An end part 40a of the third pipe portion 40 opposite to the branch portion 36a side is connected to the second heat sink 35. The end parts 39a and 40a of the pipe portions 39 and 40 can be joined to, for example, the bottom surfaces of the heat sinks 34 and 35 by brazing or the like. The end parts 39a and 40a constitute a heat radiation unit (condensation unit) that radiates the heat of the CPU 30 transported from the first pipe portion 38 to the heat sinks 34 and 35.

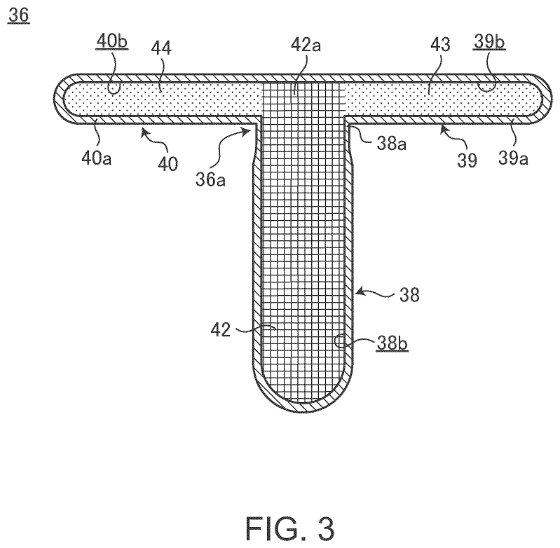

FIG. 3 is a schematic cross-sectional plan view of the heat pipe 36.

As illustrated in FIGS. 2 and 3, in the heat pipe 36 of one or more embodiments, the second pipe portion 39 and the third pipe portion 40 can be formed of one metal pipe extending in the left-right direction. The pipe portions 39 and 40 do not need to be straight. The pipe portions 39 and 40 can also be configured to have, for example, a curved shape in which the vicinity of the branch portion 36a is curved. The first pipe portion 38 is connected such that the one end part 38a is pierced to an outer surface of the metal pipe that forms the pipe portions 39 and 40, and the first pipe portion 38 and the pipe portions 39 and 40 can be joined together by brazing or the like.

As illustrated in FIG. 3, the heat pipe 36 includes a first wick 42, a second wick 43, and a third wick 44. The wicks 42 to 44 receive heat of the CPU 30 to promote the evaporation of the working fluid, and feed the working fluid that has been evaporated and then cooled and condensed by the heat radiation through the capillary phenomenon.

The first wick 42 is accommodated in a sealed space 38b of the first pipe portion 38. The second wick 43 is accommodated in a sealed space 39b of the second pipe portion 39. The third wick 44 is accommodated in a sealed space 40b of the third pipe portion 40. As described above, the pipe portions 39 and 40 of the heat pipe 36 is formed of one metal pipe. Therefore, the wicks 43 and 44 can be made of the same wick, and can fill the continuous sealed spaces 39b and 40b simultaneously.

In the heat pipe 36, the first wick 42 is formed of a fiber wick, and the second wick 43 and the third wick 44 are formed of powder wicks. The fiber wick constituting the first wick 42 can be formed by braiding or bundling thin metallic wires such as copper, aluminum, or stainless steel, or thin non-metallic wires such as carbon fiber wires. The fiber wick may be called a mesh wick. The powder wicks constituting the second wick 43 and the third wick 44 can be formed of a sintered metal obtained by sintering powder of a metal such as copper or nickel. The powder wick can be fixed to an inner surface of the pipe portions 38 and 40 by sintering fine powder that fills the sealed spaces 39b and 40b.

An end part 42a of the first wick 42 on the one end part 38a side is provided to protrude from the one end part 38a of the first pipe portion 38. Hereinafter, the end part 42a may be referred to as a “protruding portion 42a”. The protruding portion 42a protrudes into the branch portion 36a, is inserted into the wicks 43 and 44, and can be joined together.

That is, the protruding portion 42a of the first wick 42 made of a fiber wick is inserted into the wicks 43 and 44 made of powder wicks. The heat pipe 36 can join the wicks 42 to 44 together by heating and sintering the protruding portion 42a in a state of being inserted into the powder that forms the wicks 43 and 44. Accordingly, the wick can smoothly feed the working fluid condensed at the end parts 39a and 40a from the wicks 43 and 44 to the first wick 42.

As described above, the cooling module 22 of one or more embodiments is mounted in the electronic apparatus 10 including, for example, the CPU 30 as a heating element. The cooling module 22 can include the first fan 32, the second fan 33, the first heat sink 34 disposed to face the outlet 32a of the first fan 32, the second heat sink 35 disposed to face the outlet 33a of the second fan 33, and the heat pipe 36 that transports heat of the CPU 30 to the heat sinks 34 and 35. The heat pipe 36 can include the first pipe portion 38 for connecting to the CPU 30, the second pipe portion 39 that is branched from the one end part 38a of the first pipe portion 38 and is connected to the first heat sink 34, and the third pipe portion 40 that is branched from the one end part 38a of the first pipe portion 38 and is connected to the second heat sink 35.

Accordingly, in the cooling module 22, the CPU 30, which is a heating element, and the left and right heat sinks 34 and 35 disposed adjacent to the left and right fans 32 and 33 are connected to each other by the heat pipe 36 which is one component. That is, in the cooling module 22, the heat pipe 36 that transports heat to the left and right heat sinks 34 and 35 does not need to be configured as two components. Therefore, the cooling module 22 can reduce a component cost. The cooling module 22 facilitates work of assembling the heat pipe 36, so that a work cost can also be reduced. Moreover, the cooling module 22 maintains high-efficiency heat transport to the heat sinks 34 and 35 by using the heat pipe 36. Therefore, the cooling module 22 and the electronic apparatus 10 equipped with the cooling module 22 can ensure high cooling performance while reducing a cost.

The heat pipe 36 can include the wicks 42, 43, and 44 accommodated in the pipe portions 38, 39, and 40, respectively. The first wick 42 can be made of a fiber wick formed from a thin wire. The second wick 43 and the third wick 44 can be made of powder wicks formed from powder. In this case, the end part 42a of the first wick 42 formed of the fiber wick can be abutted against a side portion of the wicks 43 and 44 formed of the powder wicks and can be joined together. Accordingly, the wicks 42 to 44 that respectively fill the pipe portions 38 to 40 can be joined together. As a result, smooth liquid feeding of the working fluid is ensured at a joint portion between the first wick 42 and the wicks 43 and 44, and the heat transport efficiency of the entire heat pipe 36 is improved.

Incidentally, the heat pipe 36 of the configuration example illustrated in FIGS. 2 and 3 has a configuration in which the first pipe portion 38 is driven into and connected to a side portion of the pipe portions 39 and 40 formed of one metal pipe. Therefore, in a case where the first wick 42 of the first pipe portion 38 is made of a powder wick, it is difficult to abut the first wick 42 against the side surface of the other wicks 43 and 44 or insert the first wick 42 into the side surface of the other wicks 43 and 44. In this case, the joint portion between the first wick 42 and the wicks 43 and 44 may become unstable, and sufficient liquid feeding cannot be performed. In this regard, in the heat pipe 36, the first wick 42 is made of a fiber wick, whereby the joint portion between the first wick 42 and the wicks 43 and 44 can be firmly formed.

In particular, the first wick 42 made of a fiber wick can be provided to protrude from the one end part 38a of the first pipe portion 38. In this case, the protruding portion 42a of the first wick 42 can be inserted into the wicks 43 and 44 made of powder wicks and can be joined together. This further improves the joining strength between the first wick 42 and the wicks 43 and 44, ensuring smoother feeding of the working fluid in this portion.

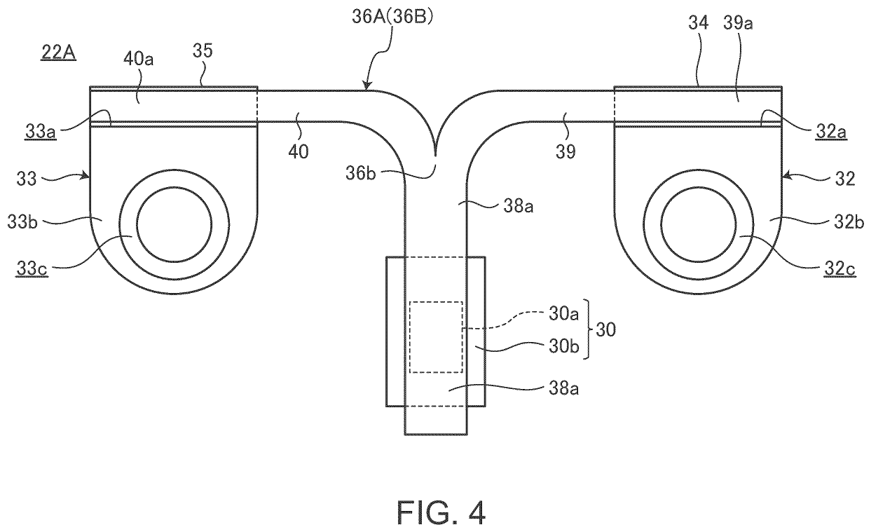

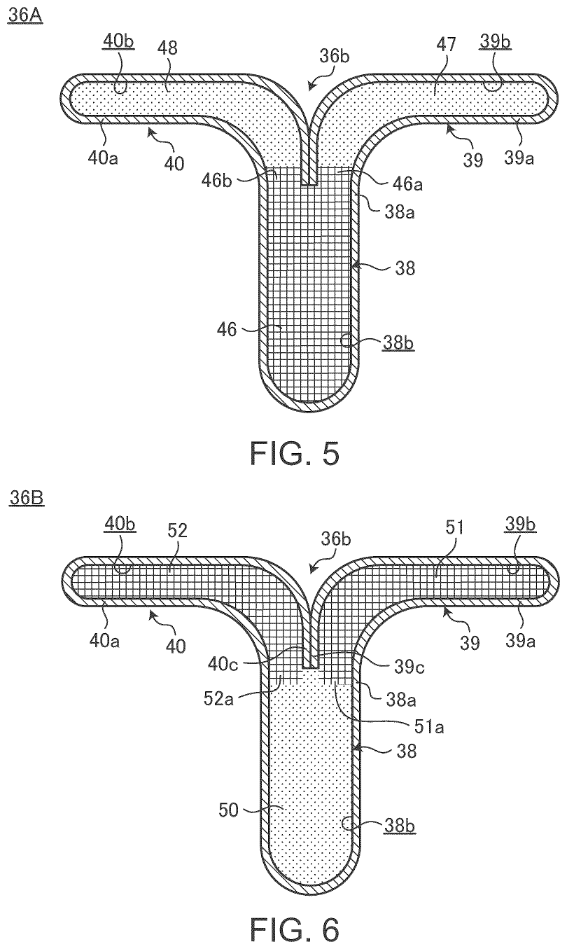

FIG. 4 is a schematic configuration diagram of a cooling module 22A according to a modification example. FIG. 5 is a schematic cross-sectional plan view of a heat pipe 36A illustrated in FIG. 4.

The cooling module 22A illustrated in FIG. 4 includes a heat pipe 36A having a configuration different from the heat pipe 36 of the cooling module 22 illustrated in FIG. 2. The heat pipe 36 described above has a configuration in which the pipe portions 38 to 40 are branched at the branch portion 36a having a substantially T-shape. More specifically, the heat pipe 36 has a configuration in which the first pipe portion 38 is driven into the side portion of the pipe portions 39 and 40 formed of one metal pipe.

With respect to this, the heat pipe 36A illustrated in FIGS. 4 and 5 has a configuration in which the pipe portions 38 to 40 are branched at a branch portion 36b having a substantially Y-shape. In the heat pipe 36A, the second pipe portion 39 and the third pipe portion 40 are formed of separate metal pipes. In the heat pipe 36A, the first pipe portion 38 has a larger diameter than the pipe portions 39 and 40. The heat pipe 36A is connected such that end parts of the pipe portions 39 and 40 opposite to the end parts 39a and 40a are pierced to the one end part 38a of the first pipe portion 38, and the first pipe portion 38 and the pipe portions 39 and 40 are joined together by brazing or the like.

As illustrated in FIG. 5, the heat pipe 36A includes a first wick 46, a second wick 47, and a third wick 48 instead of the first wick 42, the second wick 43, and the third wick 44. In the heat pipe 36A, since the second pipe portion 39 and the third pipe portion 40 are formed of separate metal pipes, the wicks 47 and 48 are individually accommodated in the sealed spaces 39b and 40b, respectively.

In such a heat pipe 36A, the first wick 46 is formed of a fiber wick, and the second wick 47 and the third wick 48 are formed of powder wicks. End parts 46a and 46b of the first wick 46 on the one end part 38a side are provided to protrude from the one end part 38a of the first pipe portion 38. Hereinafter, the end parts 46a and 46b may be referred to as “protruding portions 46a and 46b”. The protruding portions 46a and 46b protrude into the branch portion 36b, are inserted into the wicks 47 and 48, respectively, and can be joined together.

That is, the protruding portions 46a and 46b of the first wick 46 made of a fiber wick are inserted into the wicks 47 and 48 made of powder wicks. As in the case of the heat pipe 36, the heat pipe 36A can join the wicks 46 to 48 together by heating and sintering the protruding portions 46a and 46b in a state of being inserted into the powder that forms the wicks 47 and 48. As a result, even in the heat pipe 36A, the first wick 46 and the wicks 47 and 48 are firmly joined together, and the smooth liquid feeding of the working fluid in this portion is ensured.

Accordingly, even in such a cooling module 22A, the CPU 30, which is a heating element, and the left and right heat sinks 34 and 35 can be connected to each other by the heat pipe 36A which is one component. Therefore, even in the cooling module 22A and the electronic apparatus 10 equipped with the cooling module 22A, high cooling performance can be ensured while reducing a cost.

FIG. 6 is a schematic cross-sectional plan view of a heat pipe 36B according to a modification example of the heat pipe 36A illustrated in FIG. 5.

The heat pipe 36B illustrated in FIG. 6 is the same as the heat pipe 36A illustrated in FIG. 5 in that the pipe portions 38 to 40 are branched at the branch portion 36b having a substantially Y-shape. The heat pipe 36B includes a first wick 50, a second wick 51, and a third wick 52 instead of the first wick 46, the second wick 47, and the third wick 48 of the heat pipe 36A illustrated in FIG. 5.

In the heat pipe 36B, the first wick 50 is formed of a powder wick, and the second wick 51 and the third wick 52 are formed of fiber wicks. End parts 51a and 52a of the wicks 51 and 52 on the one end part 38a side are provided to protrude from one end part 39c of the pipe portion 39 and one end part 40c of the pipe portion 40 on the branch portion 36b side. Hereinafter, the end parts 51a and 52a may be referred to as “protruding portions 51a and 52a”. The protruding portions 51a and 52a can be inserted into the first wick 50 and can be joined together.

That is, the protruding portions 51a and 52a of the wicks 51 and 52 made of fiber wicks are inserted into the first wick 50 made of a powder wick. As in the case of the heat pipes 36 and 36A, the heat pipe 36B can join the wicks 50 to 52 together by heating and sintering the protruding portions 51a and 52a in a state of being inserted into the powder that forms the first wick 50. As a result, even in the heat pipe 36B, the first wick 50 and the wicks 51 and 52 are firmly joined together, and the smooth liquid feeding of the working fluid in this portion is ensured.

Accordingly, even in the cooling module 22A including such a heat pipe 36B and the electronic apparatus 10 equipped with the cooling module 22A, high cooling performance can be ensured while reducing a cost.

The present invention is not limited to the above-described embodiments, and it goes without saying that the present invention can be freely modified without departing from the gist of the present invention.

### DESCRIPTION OF SYMBOLS

10 electronic apparatus
12 cover
14 chassis
22, 22A cooling module
24 motherboard
30 CPU
32 first fan
33 second fan
34 first heat sink
35 second heat sink
36, 36A, 36B heat pipe
38 first pipe portion
39 second pipe portion
40 third pipe portion
42, 46, 50 first wick
43, 47, 51 second wick
44, 48, 52 third wick

What is claimed is:

1. A cooling module that is mounted in an electronic apparatus including a heating element, the cooling module comprising:
a first fan having an outlet;
a second fan having an outlet;
a first heat sink disposed to face the outlet of the first fan;
a second heat sink disposed to face the outlet of the second fan; and
a heat pipe configured to transport heat from the heating element to the first heat sink and the second heat sink,
wherein the heat pipe includes
a first pipe portion connected to the heating element,
a second pipe portion branched from one end part of the first pipe portion and connected to the first heat sink, and
a third pipe portion branched from the one end part of the first pipe portion and connected to the second heat sink.

2. The cooling module according to claim 1,
wherein the heat pipe includes
a first wick disposed in the first pipe portion,
a second wick disposed in the second pipe portion, and
a third wick disposed in the third pipe portion,
the first wick is a fiber wick formed from a thin wire, and
the second wick and the third wick are powder wicks formed from powder.

3. The cooling module according to claim 2,
wherein the fiber wick protrudes from the one end part of the first pipe portion, and the protruding portion is inserted into the powder wicks and joined together.

4. The cooling module according to claim 1,
wherein the heat pipe includes
a first wick disposed in the first pipe portion,
a second wick disposed in the second pipe portion, and
a third wick disposed in the third pipe portion,
the first wick is a powder wick formed from powder, and
the second wick and the third wick are fiber wicks formed from thin wires.

5. The cooling module according to claim 4,
wherein the fiber wicks protrude from one end part of the second pipe portion and one end part of the third pipe portion, and the protruding portions are inserted into the powder wick and joined together.

6. An electronic apparatus comprising:
a chassis;
a heating element disposed in the chassis; and
a cooling module disposed in the chassis and configured to cool the heating element,
wherein the cooling module includes
a first fan having an outlet,
a second fan having an outlet,
a first heat sink disposed to face the outlet of the first fan,
a second heat sink disposed to face the outlet of the second fan, and
a heat pipe configured to transport heat from the heating element to the first heat sink and the second heat sink, and
the heat pipe includes
a first pipe portion connected to the heating element,
a second pipe portion branched from one end part of the first pipe portion and connected to the first heat sink, and
a third pipe portion branched from the one end part of the first pipe portion and connected to the second heat sink.

7. The electronic apparatus according to claim 6,
wherein the heat pipe includes
a first wick disposed in the first pipe portion,
a second wick disposed in the second pipe portion, and
a third wick disposed in the third pipe portion,
the first wick is a fiber wick formed from a thin wire, and
the second wick and the third wick are powder wicks formed from powder.

8. The electronic apparatus according to claim 6,
wherein the heat pipe includes
a first wick disposed in the first pipe portion,
a second wick disposed in the second pipe portion, and
a third wick disposed in the third pipe portion,
the first wick is a powder wick formed from powder, and
the second wick and the third wick are fiber wicks formed from thin wires.
